(19) United States
(12) Patent Application Publication
(10) Pub. No.: US 2025/0293107 A1
(43) Pub. Date: Sep. 18, 2025

(54) SEMICONDUCTOR DEVICE AND METHOD FOR MANUFACTURING A SEMICONDUCTOR DEVICE

(71) Applicant: Rohm Co., Ltd., Kyoto-shi (JP)

(72) Inventor: Hiroaki MATSUBARA, Kyoto-shi (JP)

(21) Appl. No.: 19/077,802

(22) Filed: Mar. 12, 2025

(30) Foreign Application Priority Data
Mar. 15, 2024 (JP) 2024-040755

(51) Int. Cl. H01L 23/31; H01L 21/48; H01L 21/56; H01L 23/00; H01L 23/495; H01L 25/07

(52) U.S. Cl. CPC H01L 23/3121; H01L 21/56; H01L 23/49575; H01L 24/48; H01L 25/072; H01L 21/4842; H01L 2224/48137; H01L 2224/48247

(57) ABSTRACT

A semiconductor device comprises a conductive support member that includes a die pad including an obverse surface facing a first side in a thickness direction, and the first terminal apart from the die pad and entirely on a first side in a first direction regarding the die pad; a semiconductor element on the obverse surface; a wire conducted to the semiconductor element and the terminal; and a sealing resin. The resin includes a top surface facing the first side in the thickness direction; a side surface facing the first side in the first direction; the terminal exposed from the side surface; and an inclined surface connected to the top and side surfaces. The inclined surface forming a greater angle with the obverse surface than the top surface does. A portion of the wire bonded to the terminal does not overlap the inclined surface, viewed in the thickness direction.

### TECHNICAL FIELD

The present disclosure relates to a semiconductor device and a method for manufacturing a semiconductor device.

### BACKGROUND ART

Conventionally, semiconductor devices incorporating semiconductor elements (such as MOSFETs and IGBTs) with switching functions have been known. JP-A-2022-143167 discloses an example of such a semiconductor device. The disclosed semiconductor device is housed in a small outline package (SOP) and includes a semiconductor element, a die pad, a plurality of leads, and a sealing resin. The semiconductor element is mounted on the die pad. The leads are located on opposite sides of the die pad and are electrically connected to the semiconductor element by wires. The sealing resin covers the semiconductor element, and portions of the leads protrude from opposite side surfaces of the sealing resin. Typically, such a semiconductor device is bilaterally symmetrical in appearance and is provided with an externally visible marker for preventing installation in a wrong orientation. For example, a semiconductor device may be marked with a notch (an inclined surface) in the sealing resin.

For non-destructive inspection of semiconductor devices to detect delamination, voids, and cracks, scanning acoustic tomography (SAT) may be used. In SAT testing, ultrasonic waves are transmitted through a semiconductor device and the reflected waves are used to obtain information on the internal states of the semiconductor device. However, the inclined surface of the sealing resin of a semiconductor device as described above reflects ultrasonic waves and thus interferes with the SAT testing to determine the internal state of the portion below the inclined surface. Consequently, delamination at such a portion cannot be detected. If wire bonds are included in such an overlapping portion, delamination that is left undetected may result in a break in a wire.

### BRIEF DESCRIPTIONS OF THE DRAWINGS

FIG. 1 is a plan view of a semiconductor device according to a first embodiment of the present disclosure.

FIG. 2 is a plan view of the semiconductor device shown in FIG. 1, with a sealing resin shown as transparent.

FIG. 3 is a front view of the semiconductor device shown in FIG. 1.

FIG. 4 is a rear view of the semiconductor device shown in FIG. 1.

FIG. 5 is a left-side view of the semiconductor device shown in FIG. 1.

FIG. 6 is a right-side view of the semiconductor device shown in FIG. 1.

FIG. 7 is a sectional view taken along line VII-VII in FIG. 2.

FIG. 8 is a sectional view taken along line VIII-VIII in FIG. 2.

FIG. 9 is a sectional view taken along line IX-IX in FIG. 1.

FIG. 10 is a sectional view taken along line X-X in FIG. 1.

FIG. 11 is a plan view for illustrating a step of a method for manufacturing the semiconductor device shown in FIG. 1.

FIG. 12 is a plan view for illustrating a step of the method for manufacturing the semiconductor device shown in FIG. 1.

FIG. 13 is a plan view for illustrating a step of the method for manufacturing the semiconductor device shown in FIG. 1.

FIG. 14 is a sectional view taken along line XIV-XIV in FIG. 13.

FIG. 15 is a plan view for illustrating a step of the method for manufacturing the semiconductor device shown in FIG. 1.

FIG. 16 is a sectional view taken along line XVI-XVI in FIG. 15.

FIG. 17 is a plan view of a semiconductor device according to a second embodiment of the present disclosure, with a sealing resin shown as transparent.

FIG. 18 is a plan view of a semiconductor device according to a third embodiment of the present disclosure, with a sealing resin shown as transparent.

FIG. 19 is a plan view of a semiconductor device according to a fourth embodiment of the present disclosure, with a sealing resin shown as transparent.

FIG. 20 is a sectional view of a semiconductor device according to a fifth embodiment of the present disclosure.

FIG. 21 is a plan view of a semiconductor device according to a sixth embodiment of the present disclosure.

FIG. 22 is a front view of the semiconductor device shown in FIG. 21.

FIG. 23 is a plan view of a semiconductor device according to a seventh embodiment of the present disclosure.

### DETAILED DESCRIPTION OF EMBODIMENTS

The following describes the details of the present disclosure with reference to the accompanying drawings.

In the description of the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”.

### First Embodiment

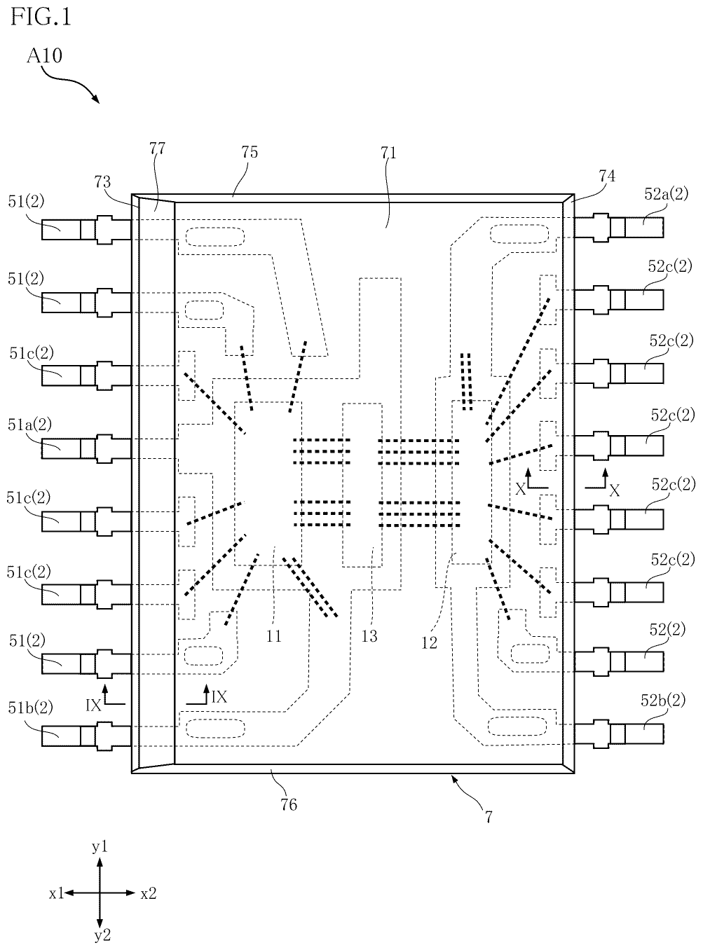

FIGS. 1 to 10 show a semiconductor device according to a first embodiment of the present disclosure. A semiconductor device A10 of the present embodiment includes a semiconductor element 11, a semiconductor element 12, an insulating element 13, a conductive support member 2, a plurality of wires 61, a plurality of wires 62, a plurality of wires 63, a plurality of wires 64, and a sealing resin 7. The conductive support member 2 includes a die pad 3, a die pad 4, a plurality of input terminals 51, and a plurality of output terminals 52. The semiconductor device A10 is for surface mounting on a wiring board of an inverter device that is incorporated in an electric vehicle or a hybrid vehicle, for example. However, the usage and function of the semiconductor device A10 are not limited to such. The semiconductor device A10 is in a small outline package (SOP), but the package type is not limited to SOP.

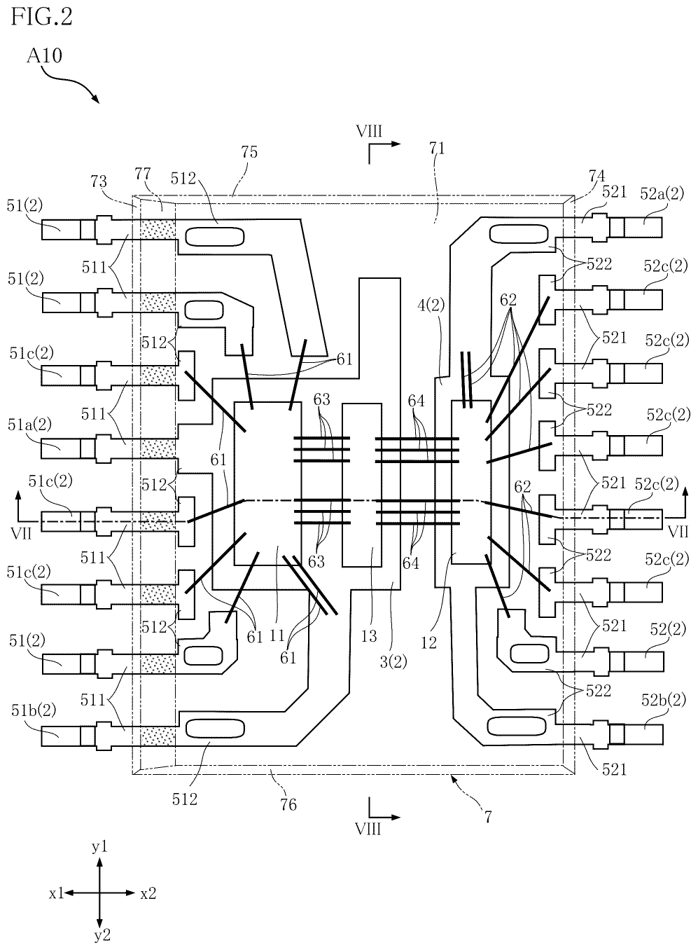

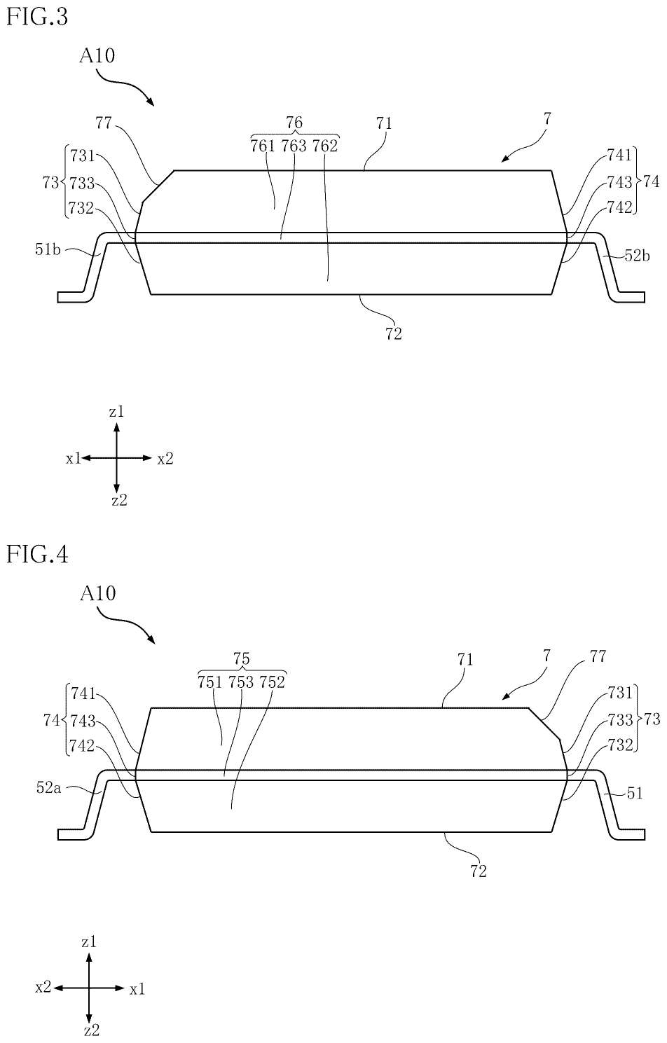

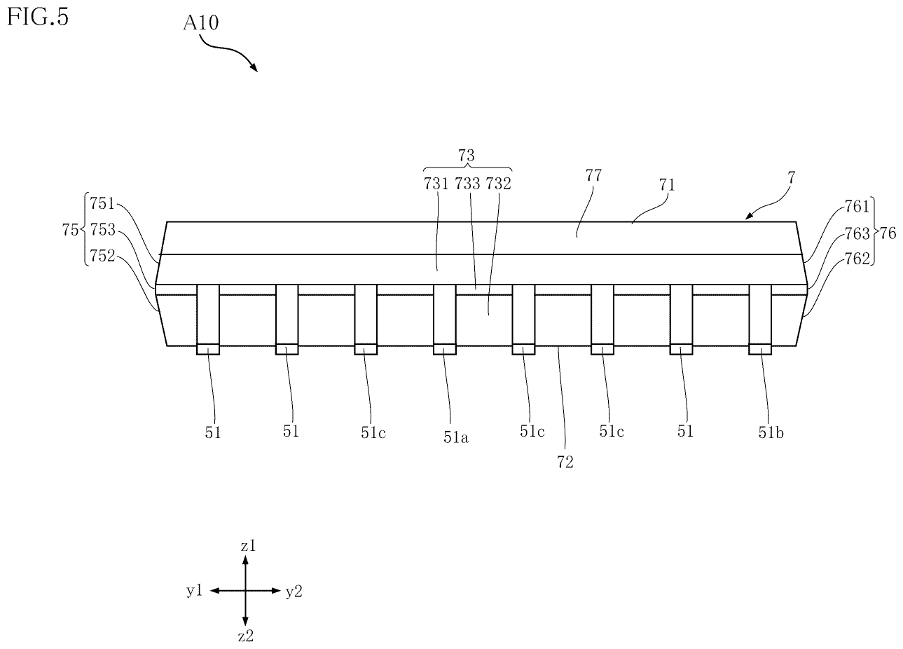

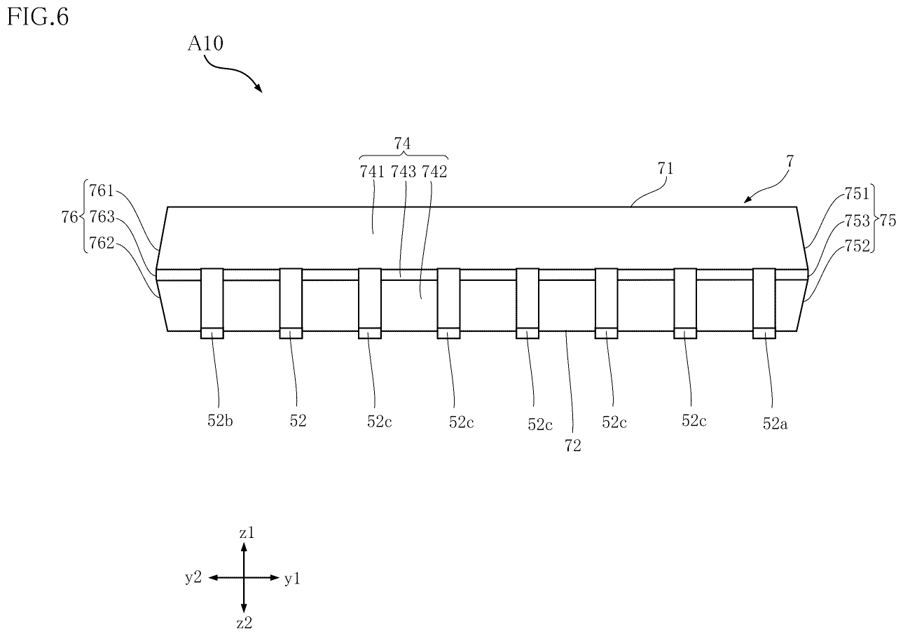

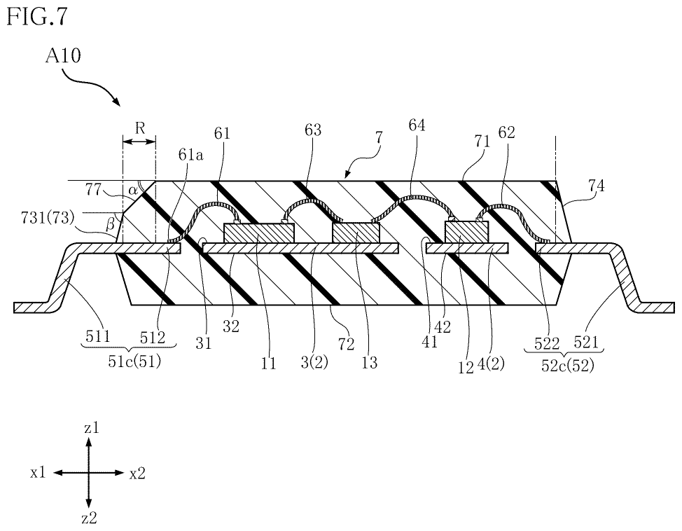

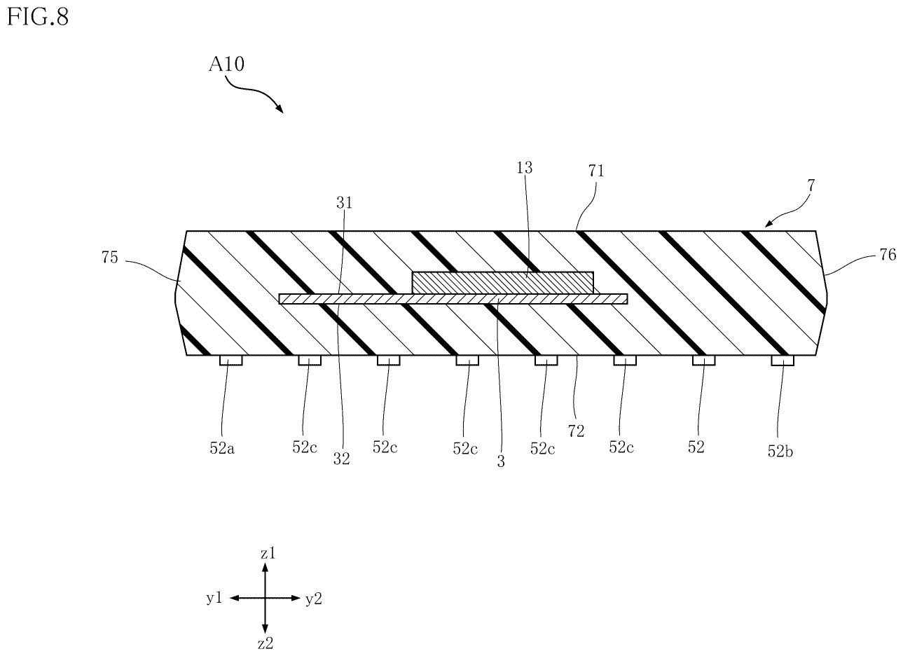

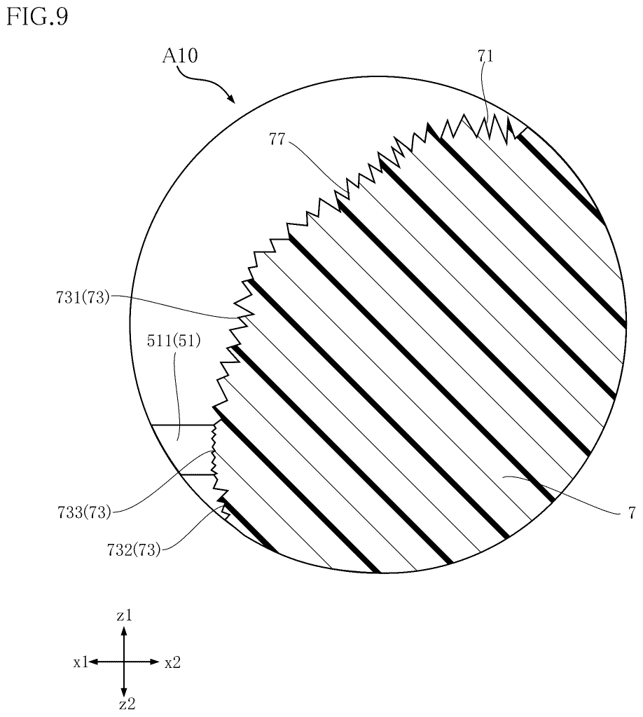

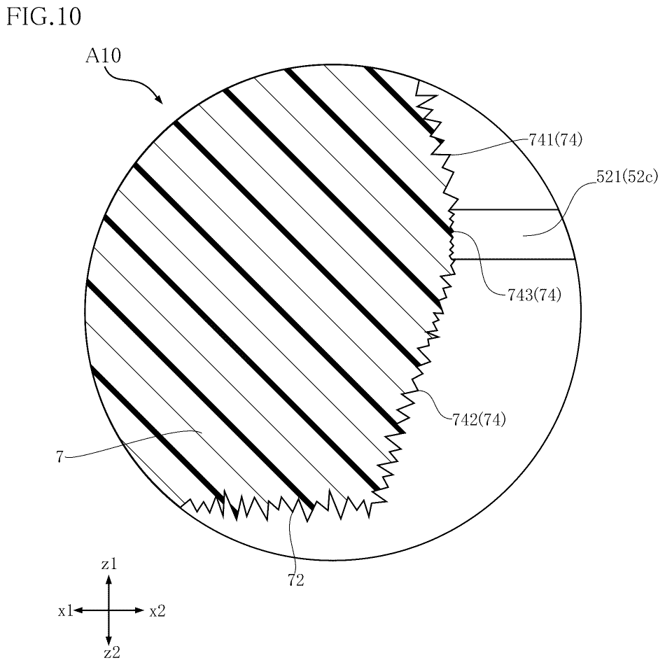

FIG. 1 is a plan view of the semiconductor device A10. FIG. 2 is a plan view of the semiconductor device A10. For the convenience of description, FIG. 2 shows the sealing resin 7 as transparent, with its outline indicated by an imaginary line (dash-double-dot line). FIG. 3 is a front view of the semiconductor device A10. FIG. 4 is a rear view of the semiconductor device A10. FIG. 5 is a left-side view of the semiconductor device A10. FIG. 6 is a right-side view of the semiconductor device A10. FIG. 7 is a sectional view taken along line VII-VII in FIG. 2. FIG. 8 is a sectional view taken along line VIII-VIII in FIG. 2. FIG. 9 is a sectional view taken along line IX-IX in FIG. 1. FIG. 10 is a sectional view taken along line X-X in FIG. 1.

The semiconductor device A10 is rectangular as viewed in the thickness direction (in plan view). For the convenience of description, the thickness direction of the semiconductor device A10 (the plan-view direction) is defined as a thickness direction z. Similarly, a direction parallel to one side of the semiconductor device A10 that is perpendicular to the thickness direction z (the lateral direction in FIGS. 1 and 2) is defined as a first direction x. The direction perpendicular to the thickness direction z and the first direction x (the vertical direction in FIGS. 1 and 2) is defined as a second direction y. One side in the thickness direction z (the upper side in FIGS. 3 to 8) is defined as a first side z1, and the other side (the lower side in FIGS. 3 to 8) is defined as a second side z2. One side in the first direction x (the left side in FIGS. 1 and 2) is defined as a first side x1, and the other side (the right side in FIGS. 1 and 2) is defined as a second side x2. One side in the second direction y (the upper side in FIGS. 1 and 2) is defined as a first side y1, and the other side (the lower side in FIGS. 1 and 2) is defined as a second side y2. Note, however, that the semiconductor device A10 is not required to have a specific shape or specific dimensions.

The semiconductor elements 11 and 12 are the main elements for the functionality of the semiconductor device A10.

As shown in FIG. 2, the semiconductor element 11 is mounted on a portion of the conductive support member 2 (the die pad 3). On the die pad 3, the semiconductor element 11 is located at the center in the second direction y and is offset from the center in the first direction x toward the first side x1. As viewed in the thickness direction z, the semiconductor element 11 is rectangular that is longer in the second direction y. The semiconductor element 11 is a control element and includes a circuit for converting a control signal inputted from an ECU, for example, into a PWM control signal, a transmission circuit for transmitting a PWM control signal to the semiconductor element 12, and a receiving circuit for receiving an electrical signal from the semiconductor element 12. The semiconductor element 11 is provided with a plurality of non-illustrated electrodes on its upper surface (the surface facing the first side z1). The electrodes are electrically connected to a circuit formed in the semiconductor element 11.

As shown in FIG. 2, the semiconductor element 12 is mounted on a portion of the conductive support member 2 (the die pad 4). The semiconductor element 12 is located at the center of the die pad 4 in the second direction y and the first direction x. As viewed in the thickness direction z, the semiconductor element 12 is rectangular that is longer in the second direction y. The semiconductor element 12 is a drive element and includes a receiving circuit for receiving a PWM control signal transmitted from the semiconductor element 11, a switching circuit (a gate driver) for switching a switching element (such as IGBT or MOSFET) on and off, and a transmission circuit for transmitting an electrical signal to the semiconductor element 11. Examples of electrical signals include an output signal of a temperature sensor disposed near a motor, for example. The semiconductor element 12 is provided with a plurality of non-illustrated electrodes on its upper surface (the surface facing the first side z1). The electrodes are electrically connected to a circuit formed in the semiconductor element 12.

As shown in FIG. 2, the insulating element 13 is mounted on the die pad 3. On the die pad 3, the insulating element 13 is located at the center in the second direction y and is offset from the center in the first direction x toward the second side x2. That is, the insulating element 13 is located on the second side x2 in the first direction x with respect to the semiconductor element 11. As will be described later, the die pad 3 is located on the first side x1 in the first direction x with respect to the die pad 4. That is, the insulating element 13 is located between the semiconductor element 11 and the semiconductor element 12 in the first direction x. As viewed in the thickness direction z, the insulating element 13 is rectangular that is longer in the second direction y.

The insulating element 13 transmits a PWM control signal and other electrical signals in an insulated state. The insulating element 13 receives a PWM control signal from the semiconductor element 11 and transmits the received PWM control signal to the semiconductor element 12 in an insulated state. The insulating element 13 receives an electrical signal from the semiconductor element 12 and transmits the received electrical signal to the semiconductor element 11 in an insulated state. In short, the insulating element 13 relays signals between the semiconductor elements 11 and 12, while insulating the semiconductor elements 11 and 12 from each other. The semiconductor element 12 (the drive element) requires a higher voltage than the semiconductor element 11 (the control element). Thus, a significant potential difference is created between the input circuit including the semiconductor element 11 and the output circuit including the semiconductor element 12. This is why the insulating element 13 needs to be provided. Specifically, in an example of an inverter device of an electric vehicle or a hybrid vehicle, the power supply voltage for the semiconductor element 11 is about 5 V, whereas the power supply voltage for the semiconductor element 12 is about 600 V or higher.

In the present embodiment, the insulating element 13 is an inductive-coupling insulating element. The inductive coupling insulating element transmits an electrical signal through the inductive coupling of two inductors (coils) that are electrically insulated. The insulating element 13 includes a substrate made of Si, for example, and inductors made of Cu on the substrate. The inductors include a transmitting-side inductor and a receiving-side inductor that are stacked one on top of the other in the thickness direction of the insulating element 13. The transmitting-side inductor and the receiving-side inductor are separated by a dielectric layer made of SiO₂, for example. The dielectric inductor electrically insulates the transmitting-side inductor and the receiving-side inductor. Although the insulating element 13 is an inductive-coupling insulating element in the present embodiment, the insulating element 13 may alternatively be a capacitive-coupling insulating element. One example of a capacitive-coupling insulating element is a capacitor. The insulating element 13 is provided with a plurality of non-illustrated electrodes on its upper surface (the surface facing the first side z1). The electrodes are electrically connected to the inductors of the insulating element 13.

The conductive support member 2 forms a conduction path connecting the semiconductor elements 11 and 12 of the semiconductor device A10 to the wiring board of an inverter device. The conductive support member 2 is made of an alloy containing Cu, for example. The conductive support member 2 is formed from a lead frame 81, which will be described later. The conductive support member 2 supports the semiconductor elements 11 and 12 and the insulating element 13. As shown in FIG. 2, the conductive support member 2 includes the die pad 3, the die pad 4, the plurality of input terminals 51, and the plurality of output terminals 52.

In the semiconductor device A10, the die pad 3 is located at the center in the second direction y and is offset from the center in the first direction x toward the first side x1. The die pad 4 is spaced apart from the die pad 3 and located on the second side x2 in the first direction x with respect to the die pad 3.

As shown in FIGS. 2 and 7, the semiconductor element 11 and the insulating element 13 are mounted on the die pad 3. The die pad 3 may be substantially rectangular as viewed in the thickness direction z. The die pad 3 has an obverse surface 31 and a reverse surface 32.

As shown in FIGS. 7 and 8, the obverse surface 31 and the reverse surface 32 are spaced apart from each other in the thickness direction z. The obverse surface 31 faces the first side z1, and the reverse surface 32 faces the second side z2. The obverse surface 31 and the reverse surface 32 are each substantially flat. The semiconductor element 11 and the insulating element 13 are bonded to the obverse surface 31 with a conductive bonding material (such as solder, metal paste, or sintered metal) not shown in the figures.

As shown in FIGS. 2 and 7, the semiconductor element 12 is mounted on the die pad 4. The die pad 4 may be substantially rectangular as viewed in the thickness direction z. The die pad 4 has an obverse surface 41 and a reverse surface 42. As shown in FIG. 7, the obverse surface 41 and the reverse surface 42 are spaced apart from each other in the thickness direction z. The obverse surface 41 faces the first side z1, and the reverse surface 42 faces the second side z2. The obverse surface 41 and the reverse surface 42 are each substantially flat. The semiconductor element 12 is bonded to the obverse surface 41 of the die pad 4 with a conductive bonding material not shown in the figures.

As shown in FIGS. 2 and 7, the die pads 3 and 4 are spaced apart from each other in the first direction x, with a portion of the sealing resin 7 interposed therebetween. The sealing resin 7 is electrically insulating as will be described later. Thus, the die pads 3 and 4 are electrically insulated from each other by the insulating element 13 and the sealing resin 7.

The input terminals 51 form a conduction path between the semiconductor device A10 and a wiring board of an inverter device when they are bonded to the wiring board. As shown in FIGS. 1, 2 and 5, the input terminals 51 are arranged at intervals in the second direction y. The input terminals 51 are on the first side x1 in the first direction x with respect to the die pad 3 and protrude from the sealing resin 7 (a side surface 73, which will be described later) toward the first side x1 in the first direction x. The plurality of input terminals 51 include a power terminal for receiving voltage, a ground terminal, an input terminal for receiving a control signal, and an input terminal for receiving other control signals. In the present embodiment, the semiconductor device A10 includes eight input terminals 51, but the number of input terminals 51 is not limited to eight. Each input terminal 51 includes a lead part 511 and a pad part 512.

The lead part 511 is substantially rectangular and extends in the first direction x. The lead part 511 includes a portion exposed from the sealing resin 7 and a portion covered with the sealing resin 7. As shown in FIG. 7, the exposed portion of the lead part 511 has been bent into a gull-wing profile. In addition, the exposed portion of the lead part 511 may be plated. For example, a plating of an alloy containing Sn, such as solder, may be formed to coat the portion exposed from the sealing resin 7. When the semiconductor device A10 is soldered to the surface of the wiring board of an inverter device, the plating layer improves the solderability of the exposed portion, while preventing erosion to the exposed portion due to soldering. The lead parts 511 of the input terminals 51 are arranged at equal intervals in the second direction y.

The pad part 512 of each input terminal 51 is connected to the end of the lead part 511 on the second side x2 in the first direction x and is wider in the second direction y than the lead part 511. Each pad part 512 as viewed in the thickness direction z may have any suitable shape that extends toward the die pad 3 and is spaced apart from the other pad parts 512 by at least a predetermined distance. The upper surface (the surface facing the first side z1) of the pad part 512 may be plated. For example, a plating layer of a metal including Ag, for example, may be formed to coat the upper surface of the pad part 512. The plating layer serves to increase the bonding strength of the wires 61, which will be described later, and also to protect the lead frame 81, which will be described later, from impact at the time of bonding the wires 61. The pad part 512 is entirely covered with the sealing resin 7. The pad part 512 is substantially flat. In the present embodiment, as shown in FIGS. 2 and 7, the pad part 512 does not overlap with a later-described inclined surface 77 of the sealing resin 7 as viewed in the thickness direction z. In FIG. 2, the stippled regions indicate the regions of the input terminals 51 that overlap with the inclined surface 77. In FIG. 7, the region R is the region of the input terminals 51 overlapping with the inclined surface 77.

The plurality of input terminals 51 include an input terminal 51a, an input terminal 51b, and a plurality of input terminals 51c. As shown in FIG. 2, the input terminal 51a is the fourth one from the first side y1 in the second direction y, among the plurality of input terminals 51. The input terminal 51a is connected by the pad part 512 to the end of the die pad 3 on the first side x1 in the first direction x. As shown in FIG. 2, the input terminal 51b is the outermost one on the second side y2 in the second direction y, among the plurality of input terminals 51. The input terminal 51b is connected by the pad part 512 to the end of the die pad 3 on the second side y2 in the second direction y. The input terminals 51a and 51b support the die pad 3. As shown in FIG. 2, the input terminals 51c are the third one, fifth one, and sixth one from the first side y1 in the second direction y, among the plurality of input terminals 51. Each input terminal 51c is located entirely on the first side x1 in the first direction x with respect to the die pad 3. Each input terminal 51, except for the input terminal 51a, has a wire 61 bonded to its pad part 512. The plurality of input terminals 51 may include a dummy terminal, to which no wire 61 is connected and thus is not electrically connected to the semiconductor element 11. The input terminals 51 are not required to have specific shapes.

Similarly to the input terminals 51, the output terminals 52 form a conduction path between the semiconductor device A10 and a wiring board of an inverter device when they are bonded to the wiring board. As shown in FIGS. 1, 2 and 6, the output terminals 52 are arranged at intervals in the second direction y. The output terminals 52 are on the second side x2 in the first direction x with respect to the die pad 4 and protrude from the sealing resin 7 (a side surface 74, which will be described later) toward the second side x2 in the first direction x. The output terminals 52 include a power terminal for receiving voltage, a ground terminal, and an output terminal. In the present embodiment, the semiconductor device A10 includes eight output terminals 52, but the number of output terminals 52 is not limited to eight. Each output terminal 52 includes a lead part 521 and a pad part 522.

The lead part 521 is substantially rectangular and extends in the first direction x. The lead part 521 includes a portion exposed from the sealing resin 7 and a portion covered with the sealing resin 7. As shown in FIG. 7, the exposed portion of the lead part 521 has been bent into a gull-wing profile. Similarly to the lead part 511, the lead part 521 may be provided with a plating layer (e.g., an alloy containing Sn) coating the portion exposed from the sealing resin 7. The lead parts 521 of the output terminals 52 are arranged at equal intervals in the second direction y.

The pad part 522 of each output terminal 52 is connected to the end of the lead part 521 on the first side x1 in the first direction x and is wider in the second direction y than the lead part 521. Each pad part 522 as viewed in the thickness direction z may have any suitable shape that extends toward the die pad 4 and is spaced apart from the other pad parts 522 by at least a predetermined distance. Similarly to the pad part 512, the pad part 522 may be provided with a plating layer (e.g., a metal, including Ag) on its upper surface (the surface facing the first side z1). The pad part 522 is entirely covered with the sealing resin 7. The pad part 522 is substantially flat. In the present embodiment, as shown in FIGS. 2 and 7, the pad part 522 does not overlap with a later-described side surface 74 of the sealing resin 7 as viewed in the thickness direction z.

The plurality of output terminals 52 include an output terminal 52a, an output terminal 52b, and a plurality of output terminals 52c. As shown in FIG. 2, the output terminal 52a is the outermost one on the first side y1 in the second direction y, among the plurality of output terminals 52. The output terminal 52a is connected by the pad part 522 to the end of the die pad 4 on the first side y1 in the second direction y. As shown in FIG. 2, the output terminal 52b is the outermost one on the second side y2 in the second direction y, among the plurality of output terminals 52. The output terminal 52b is connected by the pad part 522 to the end of the die pad 4 on the second side y2 in the second direction y. The output terminals 52a and 52b support the die pad 4. As shown in FIG. 2, the output terminals 52c are the second to sixth ones from the first side y1 in the second direction y, among the plurality of output terminals 52. Each output terminal 52c is located entirely on the second side x2 in the first direction x with respect to the die pad 4. Each output terminal 52, except for the output terminal 52b, has a wire 62 bonded to its pad part 512. The plurality of output terminals 52 may include a dummy terminal, to which no wire 62 is connected and thus is not electrically connected to the semiconductor element 12. The output terminals 52 are not required to have specific shapes.

As shown in FIGS. 2 and 7, the wires 61, 62, 63, and 64, together with the conductive support member 2, form conduction paths for the semiconductor elements 11 and 12 to perform predetermined functions. The wires 61, 62, 63, and 64 are each made of a metal, such as Au, Cu, or Al, for example.

The wires 61 form conduction paths between the semiconductor element 11 and the input terminals 51. By the wires 61, the semiconductor element 11 is electrically connected to at least one of the input terminals 51. As shown in FIG. 2, each wire 61 is bonded to an electrode of the semiconductor element 11 and the pad part 512 of an input terminal 51. As shown in FIGS. 2 and 7, the pad parts 512 do not overlap with the inclined surface 77 as viewed in the thickness direction z. Thus, a bonded portion 61a of each wire 61 that is bonded to a pad part 512 does not overlap with the inclined surface 77.

The wires 62 form conduction paths between the semiconductor element 12 and the output terminals 52. By the wires 62, the semiconductor element 12 is electrically connected to at least one of the output terminals 52. As shown in FIG. 2, each wire 62 is bonded to an electrode of the semiconductor element 12 and the pad part 522 of an output terminal 52. As shown in FIGS. 2 and 7, the pad parts 522 do not overlap with the side surface 74 as viewed in the thickness direction z. Thus, a bonded portion of each wire 62 that is bonded to a pad part 522 does not overlap with the side surface 74.

The wires 63 form conduction paths between the semiconductor element 11 and the insulating element 13. By the wires 63, the semiconductor element 11 is electrically connected to the insulating element 13. As shown in FIG. 2, each wire 63 is bonded to an electrode of the semiconductor element 11 and an electrode of the insulating element 13.

The wires 64 form conduction paths between the insulating element 13 and the semiconductor element 12. By the wires 64, the insulating element 13 is electrically connected to the semiconductor element 12. As shown in FIG. 2, each wire 64 is bonded to an electrode of the insulating element 13 and an electrode of the semiconductor element 12.

As shown in FIG. 1, the sealing resin 7 covers the semiconductor elements 11 and 12, the insulating element 13, the die pads 3 and 4, and the wires 61 to 64 and also covers a portion of each of the input terminals 51 and the output terminals 52. The sealing resin 7 is electrically insulating. The sealing resin 7 is made of a material containing a black epoxy resin, for example. As viewed in the thickness direction z, the sealing resin 7 is rectangular that is longer in the second direction y. The sealing resin 7 may be formed by transfer molding using a mold, for example.

As shown in FIGS. 3 to 6, the sealing resin 7 includes a top surface 71, a bottom surface 72, side surfaces 73 to 76, and an inclined surface 77.

The top surface 71 and the bottom surface 72 are spaced apart from each other in the thickness direction z. The top surface 71 and the bottom surface 72 face away from each other in the thickness direction z. The top surface 71 is on the first side z1 in the thickness direction z, facing the first side z1 that the obverse surface 31 of the die pad 3 faces. The bottom surface 72 is on the second side z2 in the thickness direction z, facing the second side z2 that the reverse surface 32 of the die pad 3 faces. The top surface 71 and the bottom surface 72 are each substantially flat.

Each of the side surfaces 73 to 76 are located between the top surface 71 and the bottom surface 72 in the thickness direction z. The side surface 73 is connected to the inclined surface 77 and the bottom surface 72. The side surfaces 74 to 76 are each connected to the top surface 71 and the bottom surface 72. The side surfaces 73 and 74 are spaced apart from each other in the first direction x. The side surfaces 73 and 74 face away from each other in the first direction x. The side surface 73 is on the first side x1 in the first direction x, facing the first side x1 in the first direction x. The side surface 74 is on the second side x2 in the first direction x, facing the second side x2 in the first direction x. The side surfaces 75 and 76 are spaced apart from each other in the second direction y and are each connected the side surfaces 73 and 74. The side surfaces 75 and 76 face away from each other in the second direction y. The side surface 75 is on the first side y1 in the second direction y, facing the first side y1 in the second direction y. The side surface 76 is on the second side y2 in the second direction y, facing the second side y2 in the second direction y.

As shown in FIG. 1, a portion of each input terminal 51 protrudes from the side surface 73. A portion of each output terminal 52 protrudes from the side surface 74. No portions of the conductive support member 2 protrude from the side surfaces 75 and 76.

The inclined surface 77 is located between the top surface 71 and the bottom surface 72 in the thickness direction z. The inclined surface 77 is connected to the top surface 71 and the side surface 73. The inclined surface 77 faces the first side z1 in the thickness direction z but forms a greater angle with respect to the obverse surface 31 of the die pad 3 than the top surface 71 does. In short, the inclined surface 77 is inclined relative to the top surface 71. The inclined surface 77 is provided as a marker for identifying the correct mounting orientation of the semiconductor device A10. As shown in FIG. 7, the inclination angle α of the inclined surface 77 with respect to the top surface 71 is smaller than the inclination angle β of the upper region 731 of the side surface 73 with respect to the top surface 71. In the present embodiment, the inclination angle α is 45 degrees. The inclination angle α is not limited to 45 degrees but an angle of 25 degrees or greater is preferred for the inclined surface 77 to serve as an orientation marker. As shown in FIGS. 2 and 7, the inclined surface 77 overlaps with the lead parts 511 of the input terminals 51 but not with the pad parts 512 (see the stippled regions in FIG. 2 and the region R in FIG. 7).

As shown in FIGS. 3 to 5, the side surface 73 includes an upper region 731, a lower region 732, and an intermediate region 733. The upper region 731 is connected to the inclined surface 77 at a first end in the thickness direction z and to the intermediate region 733 at a second end in the thickness direction z. The upper region 731 is inclined inward of the semiconductor device A10 from the second end to the first end. The lower region 732 is connected to the bottom surface 72 at a first end in the thickness direction z and to the intermediate region 733 at a second end in the thickness direction z. The lower region 732 is inclined inward of the semiconductor device A10 from the second end to the first end. The intermediate region 733 is connected to the upper region 731 at a first end in the thickness direction z and to the lower region 732 at a second end in the thickness direction z. The intermediate region 733 is parallel to the thickness direction z and the second direction y. As viewed in thickness direction z, the intermediate region 733 is located outside the top surface 71, the inclined surface 77, and the bottom surface 72. A portion of each input terminal 51 protrudes from the intermediate region 733.

As shown in FIGS. 3, 4, and 6, the side surface 74 includes an upper region 741, a lower region 742, and an intermediate region 743. The upper region 741 is connected to the top surface 71 at a first end in the thickness direction z and to the intermediate region 743 at a second end in the thickness direction z. The upper region 741 is inclined inward of the semiconductor device A10 from the second end to the first end. The lower region 742 is connected to the bottom surface 72 at a first end in the thickness direction z and to the intermediate region 743 at a second end in the thickness direction z. The lower region 742 is inclined inward of the semiconductor device A10 from the second end to the first end. The intermediate region 743 is connected to the upper region 741 at a first end in the thickness direction z and to the lower region 742 at a second end in the thickness direction z. The intermediate region 743 is parallel to the thickness direction z and the second direction y. As viewed in thickness direction z, the intermediate region 743 is located outside the top surface 71 and the bottom surface 72. A portion of each output terminal 52 protrudes from the intermediate region 743.

As shown in FIGS. 4 to 6, the side surface 75 includes an upper region 751, a lower region 752, and an intermediate region 753. The upper region 751 is connected to the top surface 71 at a first end in the thickness direction z and to the intermediate region 753 at a second end in the thickness direction z. The upper region 751 is inclined inward of the semiconductor device A10 from the second end to the first end. The lower region 752 is connected to the bottom surface 72 at a first end in the thickness direction z and to the intermediate region 753 at a second end in the thickness direction z. The lower region 752 is inclined inward of the semiconductor device A10 from the second end to the first end. The intermediate region 753 is connected to the upper region 751 at a first end in the thickness direction z and to the lower region 752 at a second end in the thickness direction z. The intermediate region 753 is parallel to the thickness direction z and the second direction y. As viewed in thickness direction z, the intermediate region 753 is located outside the top surface 71 and the bottom surface 72.

As shown in FIGS. 3, 5, and 6, the side surface 76 includes an upper region 761, a lower region 762, and an intermediate region 763. The upper region 761 is connected to the top surface 71 at a first end in the thickness direction z and to the intermediate region 763 at a second end in the thickness direction z. The upper region 761 is inclined inward of the semiconductor device A10 from the second end to the first end. The lower region 762 is connected to the bottom surface 72 at a first end in the thickness direction z and to the intermediate region 763 at a second end in the thickness direction z. The lower region 762 is inclined inward of the semiconductor device A10 from the second end to the first end. The intermediate region 763 is connected to the upper region 761 at a first end in the thickness direction z and to the lower region 762 at a second end in the thickness direction z. The intermediate region 763 is parallel to the thickness direction z and the second direction y. As viewed in thickness direction z, the intermediate region 763 is located outside the top surface 71 and the bottom surface 72.

As shown in FIGS. 9 and 10, in the present embodiment, the sealing resin 7 has a greater surface roughness on the top surface 71, the inclined surface 77, the bottom surface 72, the upper region 731 and the lower region 732 of the side surface 73, and the upper region 741 and the lower region 742 of the side surface 74 than on the intermediate region 733 of the side surface 73 and the intermediate region 743 of the side surface 74. Preferably, the top surface 71 and the bottom surface 72 each have a surface roughness of 5 μmRz or greater and 20 μmRz or smaller.

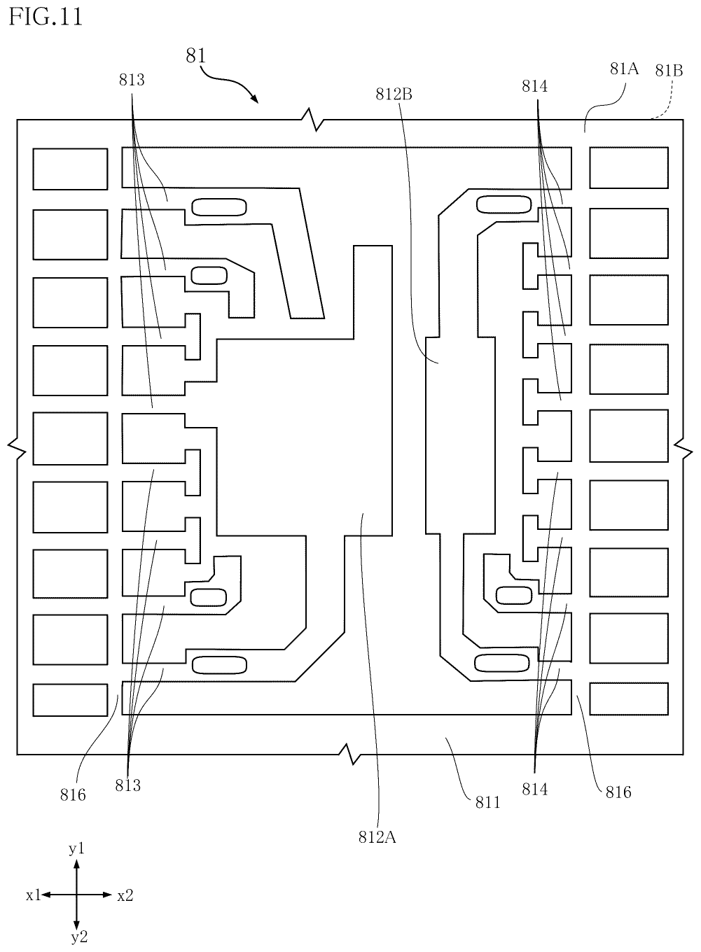

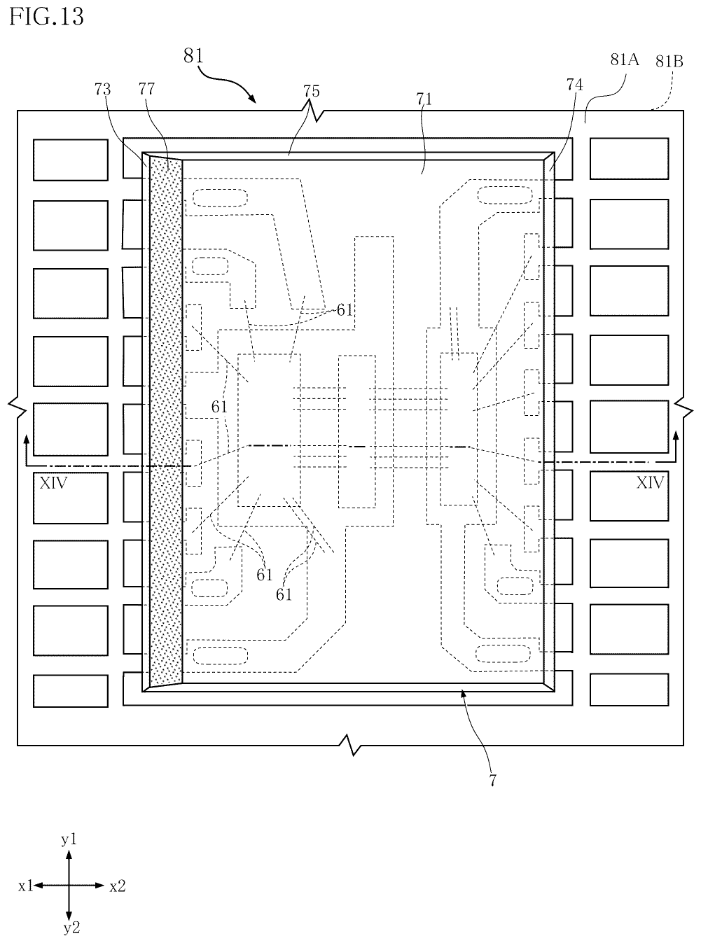

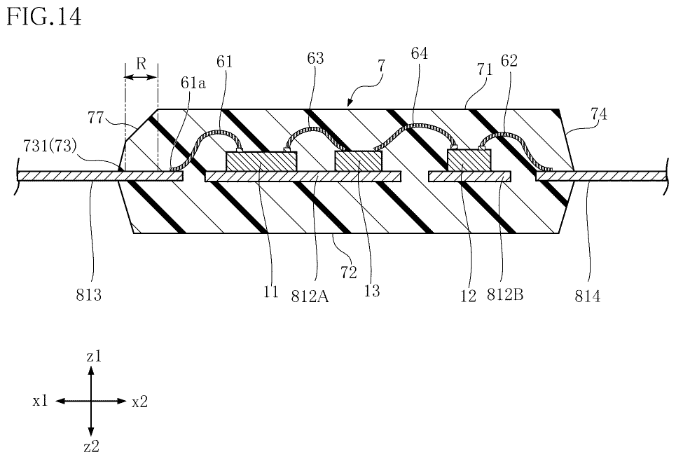

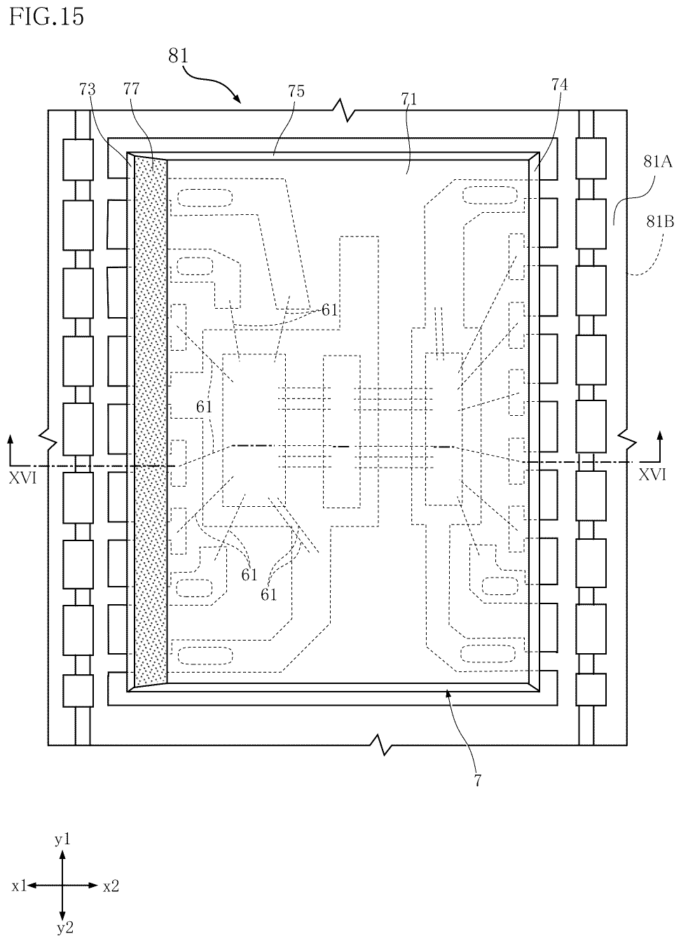

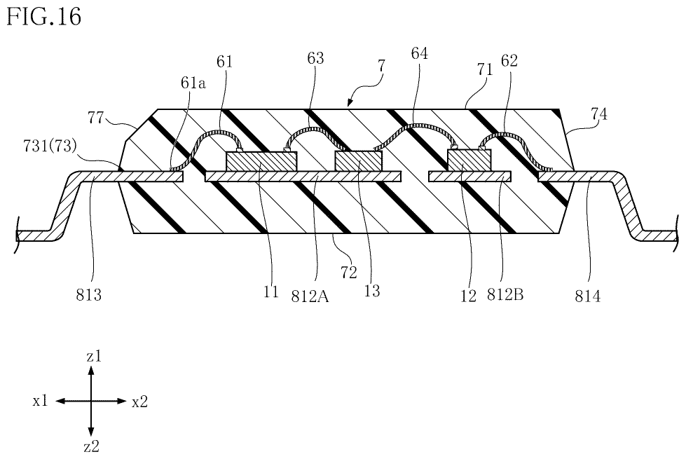

Next, the following describes an example of a method for manufacturing a semiconductor device A10, with reference to FIGS. 11 to 16. FIGS. 11 to 13 and 15 are plan views of the semiconductor device A10, illustrating the steps of the method. FIG. 14 is a sectional view taken along line XIV-XIV in FIG. 13 and corresponds to FIG. 7. FIG. 16 is a sectional view taken along line XVI-XVI in FIG. 15 and corresponds to FIG. 7. The first direction x, the second direction y, and the thickness direction z in these figures are the same as those in FIGS. 1 to 10.

First, a lead frame 81 is prepared as shown in FIG. 11. The lead frame 81 is a plate-like material. In the present embodiment, the base material of the lead frame 81 is Cu. The lead frame 81 is formed from a metal plate by etching or by punching, for example. The lead frame 81 has an obverse surface 81A and a reverse surface 81B spaced apart in the thickness direction z. The lead frame 81 includes an outer frame 811, a die pad 812A, a die pad 812B, a plurality of first leads 813, a plurality of second leads 814, and a plurality of dam bars 816. Of these portions, the outer frame 811 and the dam bars 816 do not form part of the semiconductor device A10. The die pad 812A will later form a die pad 3. The die pad 812B is the portion that will later form a die pad 4. The first leads 813 are the portions that will later form input terminals 51. The second leads 814 are the portions that will later form output terminals 52.

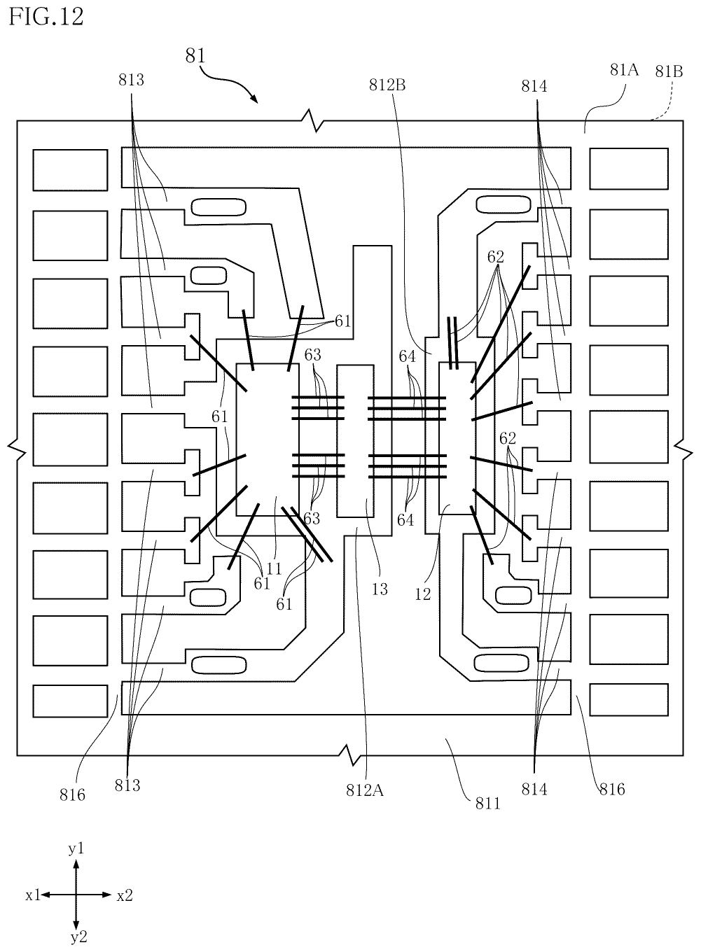

Subsequently, as shown in FIG. 12, the semiconductor element 11 and the insulating element 13 are bonded to the die pad 812A by die bonding, and the semiconductor element 12 is bonded to the die pad 812B by die bonding. After these processes, a plurality of wires 61 to 64 are formed by wire bonding.

The process of forming a wire 61 begins with moving a capillary downward toward the semiconductor element 11, pressing the wire tip against a predetermined electrode. In this state, by the combined action of the weight of the capillary, ultrasonic vibrations from the capillary, and other factors, the wire tip is caused to bond to the electrode, making a. In this way, the first bond is made. The capillary is then moved upward while continuously feeding the bonding wire. As a result, a ball bond is formed on the electrode. The capillary is then moved to a position directly above the portion of the first lead 813 where the pad part 512 of an input terminal 51 will be formed. The capillary is then moved downward to press the tip of the capillary against the bonding surface. As a result, the wire is sandwiched between the capillary tip and the bonding surface and is caused to bond to the bonding surface. In this way, the second bond is made. The capillary is then moved upward to break the wire.

In the process of forming a wire 62, the first bond is made to an electrode of the semiconductor element 12, and the second bond is made to the portion of the second lead 814 where the pad part 522 of an output terminal 52 is formed. In the process of forming a wire 63, the first bond is made to an electrode of the semiconductor element 11, and the second bond is made to an electrode of the insulating element 13. In the process of forming a wire 64, the first bond is made to an electrode of the semiconductor element 12, and the second bond is made to an electrode of the insulating element 13. In the process of forming wires 63 and 64, the objects to perform the first bond and the objects to perform the second bond may be made opposite to those in the examples described above.

Subsequently, as shown in FIGS. 13 and 14, a sealing resin 7 is formed. The sealing resin 7 is formed by transfer molding. In this process, the lead frame 81 is placed into a mold having a plurality of cavities. Here, portions of the lead frame 81 corresponding to the portions of the conductive support member 2 thar are covered with the sealing resin 7 when the semiconductor device A10 is completed are placed into one of the cavities. Then, melted resin for forming a sealing resin 7 is introduced from a pot into the cavities through runners, and is then allowed to solidify. Subsequently, resin burrs having been formed on the outside of the cavity are removed using high-pressure water, for example. This completes the formation of the sealing resin 7. The sealing resin 7 thus formed has a top surface 71 and a bottom surface 72 facing away from each other in the thickness direction z, side surfaces 73 and 74 facing away from each other in the first direction x, side surfaces 75 and 76 facing away from each other in the second direction y, and an inclined surface 77 (shown with dots in FIG. 13) connected to the top surface 71 and the side surface 73. The inclined surface 77 is formed not to overlap with the bonded portion 61a of the wire 61 that is bonded to the lead frame 81.

Subsequently, portions of the lead frame 81 exposed from the sealing resin 7 are bent as shown in FIGS. 15 and 16. The lead frame 81 is not cut before this process. Then, dicing is performed by cutting the exposed portions, so that die pads 812A and 812B, a plurality of first leads 813, and a plurality of second leads 814, all of which are connected to one another via the outer frame 811 and the dam bars 816, are appropriately separated. Through the above processes, the semiconductor device A10 is manufactured.

The following describes operation and effects of the semiconductor device A10.

In the present embodiment, the sealing resin 7 has the inclined surface 77 connected to the top surface 71 and the side surface 73. The inclined surface 77 is inclined relative to the top surface 71. The pad parts 512 to which the wires 61 are bonded do not overlap with the inclined surface 77 as viewed in the thickness direction z. Thus, the semiconductor device A10 ensures that delamination of the sealing resin 7 at a pad part 512 is detectable by SAT testing. Consequently, the semiconductor device A10 will reduce the risk of breakage of the wires 61 due to delamination of the sealing resin 7 at the pad parts 512.

In the present embodiment, the insulating element 13 relays signals between the semiconductor elements 11 and 12 while insulating the semiconductor elements 11 and 12 from each other. Thus, although the potential difference can be significant between the input circuit including the semiconductor element 11 and the output circuit including the semiconductor element 12, the semiconductor device A10 increases the dielectric strength.

In the present embodiment, the conductive support member 2 includes the die pads 3 and 4, the input terminals 51, and the output terminals 52. The input terminals 51 protrude from the side surface 73, and the output terminals 52 from the side surface 74. In contrast, no portions of the conductive support member 2 protrude from the side surfaces 75 and 76. That is, no metal parts exposed from the sealing resin 7 are present between the input terminals 51 and the output terminals 52. This increases the distance of insulation between the input terminals 51 and the output terminals 52. The semiconductor device A10 therefore has a higher dielectric strength as compared with a configuration in which the conductive support member 2, such as a support lead, is exposed from the side surface 75 or 76.

In the present embodiment, the steps of manufacturing the semiconductor device A10 include bending the portions of the lead frame 81 exposed from the sealing resin 7 and then dicing by cutting the exposed portions of the lead frame 81. Performing the cutting and the bending in the reverse order is not possible without support leads that secure the sealing resin 7 to the outer frame 811 of the lead frame 81. Otherwise, by the cutting of the exposed portions, the dicing of the exposed portions would be performed before they are bent. The method of the present embodiment enables the manufacture of the semiconductor device A10 without the need for support leads in the lead frame 81. The semiconductor device A10 thus has no portions of the conductive support member 2 exposed on the side surfaces 75 and 76.

In the present embodiment, the sealing resin 7 has a greater surface roughness on the top surface 71, the inclined surface 77, the bottom surface 72, the upper region 731 and the lower region 732 of the side surface 73, and the upper region 741 and the lower region 742 of the side surface 74 than on the intermediate region 733 of the side surface 73 and the intermediate region 743 of the side surface 74. This serves to increases the top-side creepage distance from the input terminals 51 to the output terminals 52 along the upper region 731 of the side surface 73 of the sealing resin 7, the top surface 71, and the upper region 741 of the side surface 74, as well as the bottom-side creepage distance from the input terminals 51 to the output terminals 52 along the lower region 732 of the side surface 73 of the sealing resin 7, the bottom surface 72, and the lower region 742 of the side surface 74. This further increases the dielectric strength of the semiconductor device A10.

For the semiconductor device A10, the voltage applied to the semiconductor element 12 is 600 V higher than the voltage applied to the semiconductor element 11. In view of the significant potential difference that can occur between the input circuit and the output circuit, an arrangement to further increase the dielectric strength, in addition to the provision of the insulating element 13, is preferable for making the semiconductor device A10 more reliable.

Note that that the present disclosure is not limited to this embodiment in which the inclined surface 77 does not overlap with the pad parts 512 of the input terminals 51 as viewed in the thickness direction z. It is acceptable that the inclined surface 77 overlaps with a portion of the pad part 512 of each input terminal 51 as viewed in the thickness direction z. However, the inclined surface 77 does not overlap with the bonded portion 61a of any wire 61 as viewed in the thickness direction z.

In addition, the present disclosure is not limited to this embodiment in which the sealing resin 7 has a greater surface roughness on the top surface 71, the inclined surface 77, the bottom surface 72, the upper region 731 and the lower region 732 of the side surface 73, and the upper region 741 and the lower region 742 of the side surface 74 than on the intermediate region 733 of the side surface 73 and the intermediate region 743 of the side surface 74. For example, the surface roughness of the sealing resin 7 may be substantially uniform across the surfaces 71 to 77. In this case, the surface roughness of the surfaces 71 to 77 may be relatively low or relatively high (e.g., 5 μmRz or higher and 20 μmRz or lower).

The present disclosure is not limited to this embodiment in which the conductive support member 2 is not exposed on the side surfaces 75 and 76. For example, a support lead may be exposed on a side surface 75 or 76.

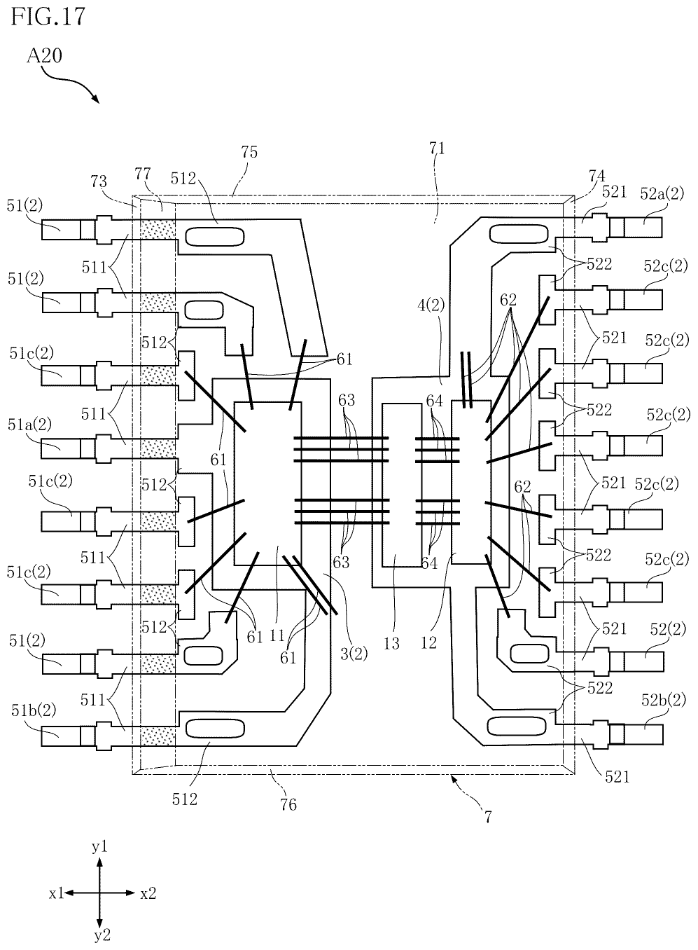

FIGS. 17 to 23 show other embodiments of the present disclosure. In these figures, elements that are identical or similar to those of the embodiment described above are indicated by the same reference numerals.

### Second Embodiment

FIG. 17 is a view for illustrating a semiconductor device A20 according to a second embodiment of the present disclosure. FIG. 17 is a plan view of the semiconductor device A20 and corresponds to FIG. 2. For the convenience of description, FIG. 17 shows the sealing resin 7 as transparent, with its outline indicated by an imaginary line (dash-double-dot line). The semiconductor device A20 of the present embodiment differs from the first embodiment in that the insulating element 13 is mounted on the die pad 4. Other configuration and operation of the present embodiment are the same as those of the first embodiment. The present embodiment may be combined with any part of the first embodiment as desired.

In the present embodiment, the insulating element 13 is mounted on the die pad 4. On the die pad 4, the insulating element 13 is located at the center in the second direction y and is offset from the center in the first direction x toward the first side x1. That is, the insulating element 13 is located on the first side x1 in the first direction x with respect to the semiconductor element 12. The die pad 4 is located on the second side x2 in the first direction x with respect to the die pad 3. That is, the insulating element 13 is located between the semiconductor element 11 and the semiconductor element 12 in the first direction x.

In this embodiment, the sealing resin 7 has an inclined surface 77 that is connected to the top surface 71 and the side surface 73 and is inclined relative to the top surface 71. The pad parts 512 to which the wires 61 are bonded do not overlap with the inclined surface 77 as viewed in the thickness direction z. Thus, the semiconductor device A20 ensures that delamination of the sealing resin 7 at the pad parts 512 is detectable by SAT testing. Consequently, the semiconductor device A20 will reduce the risk of breakage of the wires 61 due to delamination of the sealing resin 7 at the pad parts 512. Also, the semiconductor device A20 has a configuration in common with the semiconductor device A10, thereby achieving the same effect as the semiconductor device A10.

### Third Embodiment

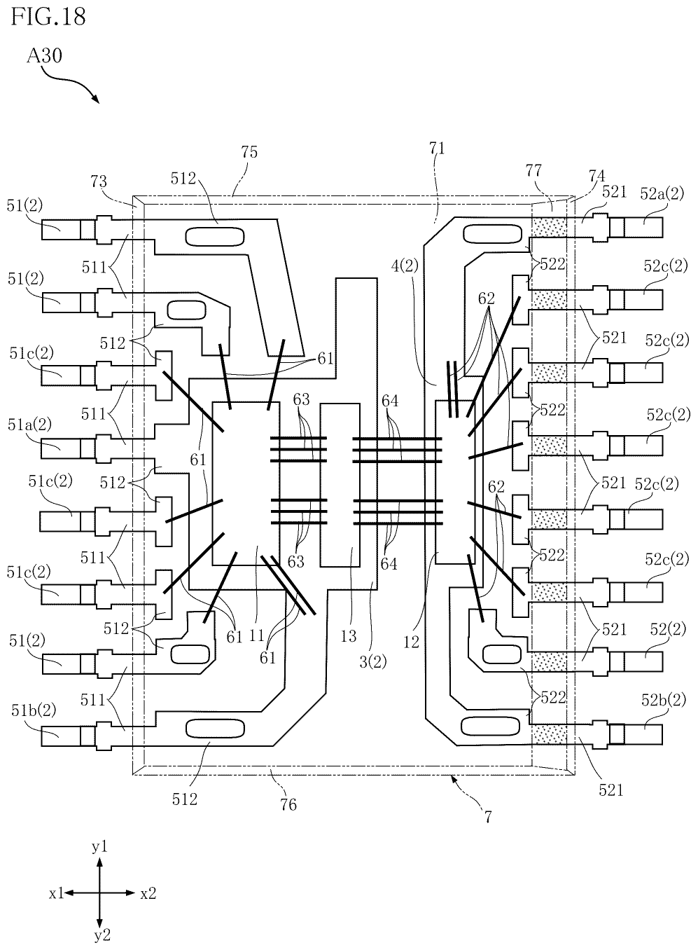

FIG. 18 is a view for illustrating a semiconductor device A30 according to a third embodiment of the present disclosure. FIG. 18 is a plan view of the semiconductor device A30 and corresponds to FIG. 2. For the convenience of description, FIG. 18 shows the sealing resin 7 as transparent, with its outline indicated by an imaginary line (dash-double-dot line). The semiconductor device A30 of the present embodiment differs from the first embodiment in the location of the inclined surface 77 in the sealing resin 7. Other configuration and operation of the present embodiment are the same as those of the first embodiment. The present embodiment may be combined with any part of the first and second embodiments as desired.

In the present embodiment, the inclined surface 77 is connected to the top surface 71 and the side surface 74 and inclined relative to the top surface 71. As viewed in the thickness direction z, the inclined surface 77 overlaps with the lead parts 521 of the output terminals 52 but not with the pad parts 522. In FIG. 18, the stippled regions indicate the regions of the output terminals 52 that overlap with the inclined surface 77. Since the pad parts 522 do not overlap with the inclined surface 77 as viewed in the thickness direction z, the bonded portions of the wires 62 that are bonded to the pad part 522 do not overlap with the inclined surface 77.

In this embodiment, the sealing resin 7 has the inclined surface 77 that is connected to the top surface 71 and the side surface 74 and is inclined relative to the top surface 71. The pad parts 522 to which the wires 62 are bonded do not overlap with the inclined surface 77 as viewed in the thickness direction z. Thus, the semiconductor device A30 ensures that delamination of the sealing resin 7 at the pad parts 522 is detectable by SAT testing. Consequently, the semiconductor device A30 will reduce the risk of breakage of the wires 62 due to delamination of the sealing resin 7 at the pad parts 522. Also, the semiconductor device A30 has a configuration in common with the semiconductor device A10, thereby achieving the same effect as the semiconductor device A10.

### Fourth Embodiment

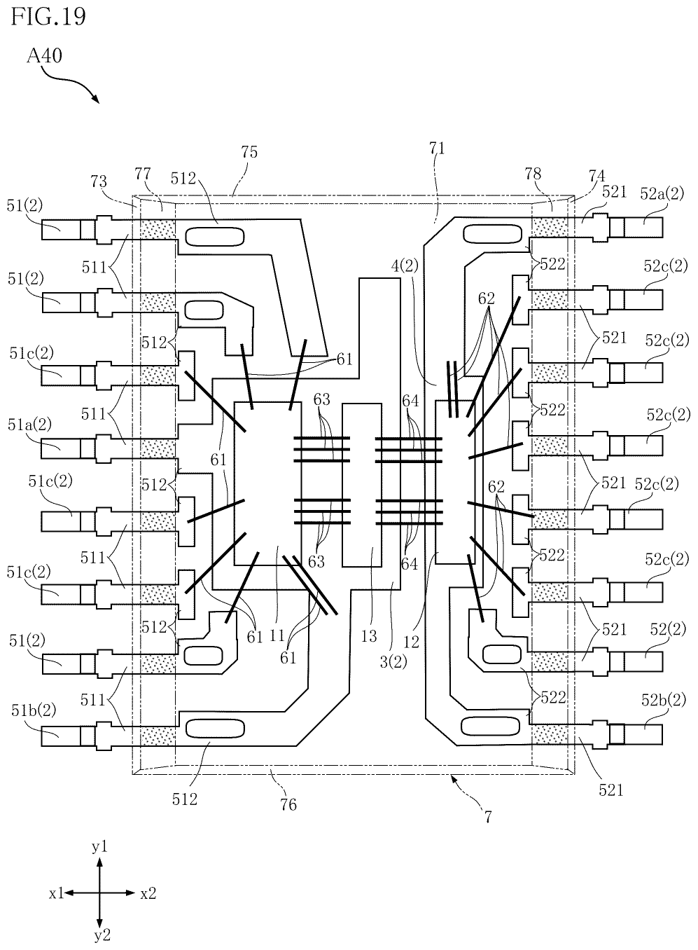

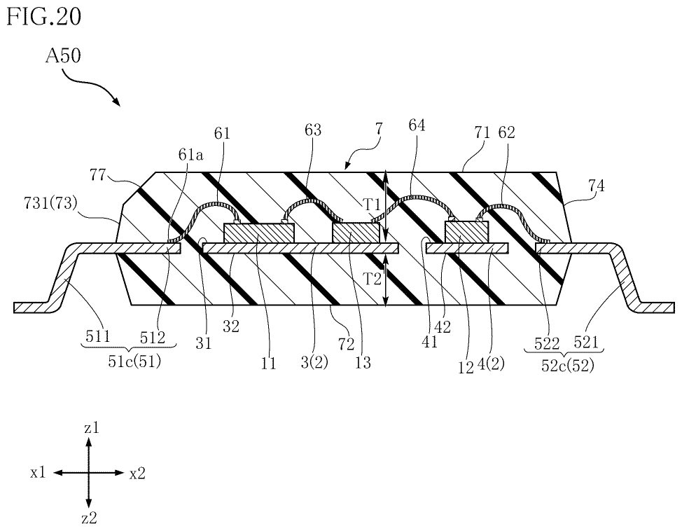

FIG. 19 is a view for illustrating a semiconductor device A40 according to a fourth embodiment of the present disclosure. FIG. 19 is a plan view of the semiconductor device A40 and corresponds to FIG. 2. For the convenience of description, FIG. 19 shows the sealing resin 7 as transparent, with its outline indicated by an imaginary line (dash-double-dot line). The semiconductor device A40 of the present embodiment differs from the first embodiment in the shape of the sealing resin 7. Other configuration and operation of the present embodiment are the same as those of the first embodiment. The present embodiment may be combined with any part of the first to third embodiments as desired.

In the present embodiment, the sealing resin 7 has an additional inclined surface 78. The inclined surface 78 is connected to the top surface 71 and the side surface 74 and inclined relative to the top surface 71. As viewed in the thickness direction z, the inclined surface 78 overlaps with the lead parts 521 of the output terminals 52 but not with the pad parts 522. In FIG. 19, the stippled regions indicate the regions of the input terminals 51 that overlap with the inclined surface 77 and the regions of the output terminals 52 that overlap with the inclined surface 78. Since the pad parts 522 do not overlap with the inclined surface 78 as viewed in the thickness direction z, the bonded portions of the wires 62 that are bonded to the pad part 522 do not overlap with the inclined surface 78.

In this embodiment, the sealing resin 7 has the inclined surface 77 that is connected to the top surface 71 and the side surface 73 and is inclined relative to the top surface 71, and also has the inclined surface 78 that is connected to the top surface 71 and the side surface 74 and is inclined relative to the top surface 71. The pad parts 512 to which the wires 61 are bonded do not overlap with the inclined surface 77 as viewed in the thickness direction z. Thus, the semiconductor device A40 ensures that delamination of the sealing resin 7 at the pad parts 512 is detectable by SAT testing. Consequently, the semiconductor device A40 will reduce the risk of breakage of the wires 61 due to delamination of the sealing resin 7 at the pad parts 512. Additionally, the pad parts 522 to which the wires 62 are bonded do not overlap with the inclined surface 78 as viewed in the thickness direction z. Thus, the semiconductor device A40 ensures that delamination of the sealing resin 7 at the pad parts 522 is detectable by SAT testing. Consequently, the semiconductor device A40 will reduce the risk of breakage of the wires 62 due to delamination of the sealing resin 7 at the pad parts 522. Also, the semiconductor device A40 has a configuration in common with the semiconductor device A10, thereby achieving the same effect as the semiconductor device A10.

### Fifth Embodiment

FIG. 20 is a view for illustrating a semiconductor device A50 according to a fifth embodiment of the present disclosure. FIG. 20 is a sectional view of the semiconductor device A50 and corresponds to FIG. 7. The semiconductor device A50 of the present embodiment differs from the first embodiment in the dimension of the sealing resin 7 in the thickness direction z. Other configuration and operation of the present embodiment are the same as those of the first embodiment. The present embodiment may be combined with any part of the first to fourth embodiments as desired.

In the present embodiment, when measured from the die pad 3 in the thickness direction, the sealing resin 7 has a thickness T1 on the first side z1 in the thickness direction z (the dimension from the obverse surface 31 of the die pad 3 to the top surface 71 of the sealing resin 7) and a thickness T2 on the second side z2 of the thickness direction z (the dimension from the reverse surface 32 of the die pad 3 to the bottom surface 72 of the sealing resin 7), where the thickness T1 is greater than the thickness T2.

In this embodiment, the sealing resin 7 has an inclined surface 77 that is connected to the top surface 71 and the side surface 73 and is inclined relative to the top surface 71. The pad parts 512 to which the wires 61 are bonded do not overlap with the inclined surface 77 as viewed in the thickness direction z. Thus, the semiconductor device A50 ensures that delamination of the sealing resin 7 at the pad parts 512 is detectable by SAT testing. Consequently, the semiconductor device A50 will reduce the risk of breakage of the wires 61 due to delamination of the sealing resin 7 at the pad parts 512. Also, the semiconductor device A50 has a configuration in common with the semiconductor device A10, thereby achieving the same effect as the semiconductor device A10. Further, the thickness T1 of the sealing resin 7 measured from the die pad 3 in the thickness direction z on first side z1 is smaller than the thickness T2 on the second side z2. Thus, the semiconductor device A50 ensures that the top-side creepage distance is not shorter than the bottom-side creepage distance despite the presence of the inclined surface 77 on the sealing resin 7. In addition, the thickness T1 that is greater than the thickness T2 ensures the wires 61 to 64 to have a higher loop height with respect to the top surface 71.

### Sixth Embodiment

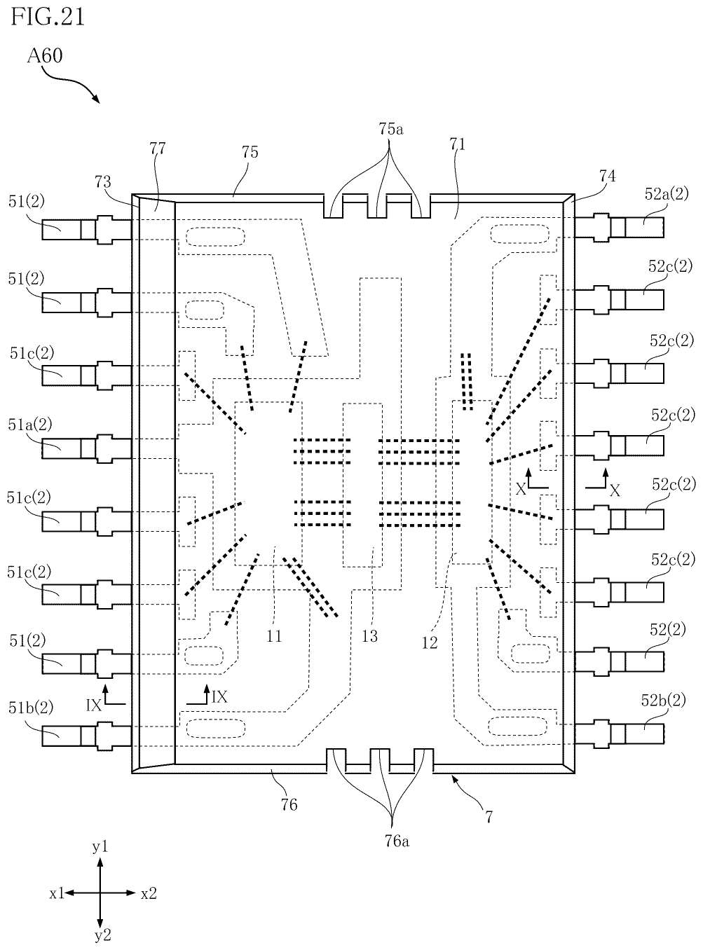

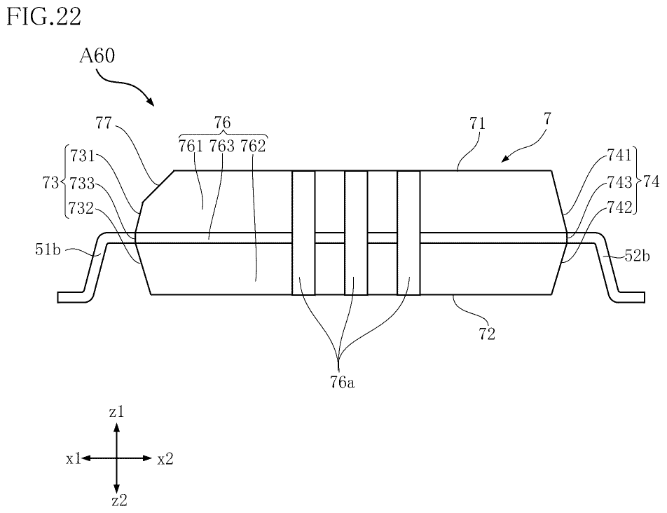

FIGS. 21 and 22 are views for illustrating a semiconductor device A60 according to a sixth embodiment of the present disclosure. FIG. 21 is a plan view of the semiconductor device A60 and corresponds to FIG. 1. FIG. 22 is a front view of the semiconductor device A60 and corresponds to FIG. 3. The semiconductor device A60 of the present embodiment differs from the first embodiment in the shape of the sealing resin 7. Other configuration and operation of the present embodiment are the same as those of the first embodiment. The present embodiment may be combined with any part of the first to fifth embodiments as desired.

In the present embodiment, the sealing resin 7 has slots 75a and 76a. The slot 75a is recessed from the side surface 75 in the second direction y toward the second side y2 and extends from the top surface 71 to the bottom surface 72 in the thickness direction z. In the present embodiment, the sealing resin 7 has three slots 75a at equal intervals. However, the number of slots 75a is not limited to three. The slot 76a is recessed from the side surface 76 in the second direction y toward the first side y1 and extends from the top surface 71 to the bottom surface 72 in the thickness direction z. In the present embodiment, the sealing resin 7 has three slots 76a at equal intervals. However, the number of slots 76a is not limited to three. In the present embodiment, the slots 75a and 76a are each rectangular as viewed in the thickness direction z. The shape of each of the slots 75a and 76a as viewed in the thickness direction z is not limited to a rectangle and may be a semicircle, for example.

In this embodiment, the sealing resin 7 has an inclined surface 77 that is connected to the top surface 71 and the side surface 73 and is inclined relative to the top surface 71. The pad parts 512 to which the wires 61 are bonded do not overlap with the inclined surface 77 as viewed in the thickness direction z. Thus, the semiconductor device A60 ensures that delamination of the sealing resin 7 at the pad parts 512 is detectable by SAT testing. Consequently, the semiconductor device A60 will reduce the risk of breakage of the wires 61 due to delamination of the sealing resin 7 at the pad parts 512. Also, the semiconductor device A60 has a configuration in common with the semiconductor device A10, thereby achieving the same effect as the semiconductor device A10. In addition, the sealing resin 7 of the present embodiment has the slots 75a each recessed from the side surface 75 in the second direction y toward the second side y2. This provides a longer creepage distance from the outermost input terminal 51 on the first side x1 in the first direction x to the output terminal 52a along the side surfaces 73, 75, and 74 of the sealing resin 7 than that without the slots 75a. The sealing resin 7 also has the slots 76a each recessed from the side surface 76 in the second direction y toward the first side y1. This provides a longer creepage distance from the input terminal 51b to the output terminal 52b along the side surfaces 73, 76, and 74 of the sealing resin 7 than that without the slots 76a. This further increases the dielectric strength of the semiconductor device A60.

The present disclosure is not limited to the embodiment in which the slots 75a and 76a extends in the thickness direction z from the top surface 71 to the bottom surface 72. It is sufficient that a slot 75a (76a) extends at least across the intermediate region 753 of the side surface 75 (the intermediate region 763 of the side surface 76. Instead of each slots 75a and 76a, the semiconductor device A60 may be provided with a first protrusion that protrudes from the side surface 75 toward the first side y1 in the second direction y and a second protrusion that extends from the side surface 76 toward the second side y2 in the second direction y.

### Seventh Embodiment

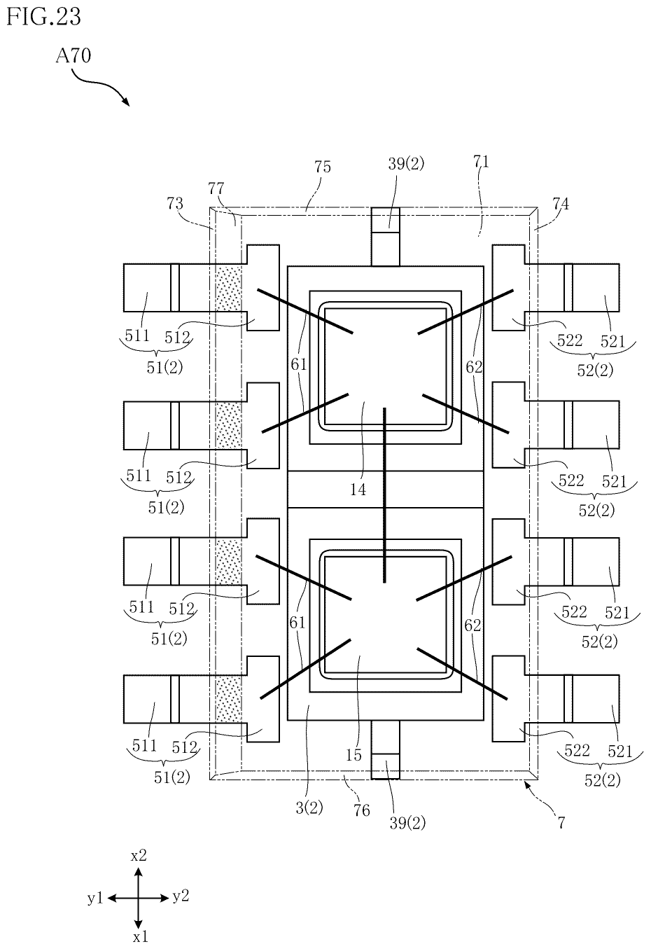

FIG. 23 is a view for illustrating a semiconductor device A70 according to a seventh embodiment of the present disclosure. FIG. 23 is a plan view of the semiconductor device A70 and corresponds to FIG. 1. The semiconductor device A70 of the present embodiment differs from the first embodiment in the shape of the conductive support member 2 and the arrangement of the semiconductor elements. Other configuration and operation of the present embodiment are the same as those of the first embodiment. The present embodiment may be combined with any part of the first to sixth embodiments as desired.

In the present embodiment, the die pad 3 has a securing part 39 on opposite ends of the first direction x. Each securing part 39 is for holding the die pad 3 integral with the lead frame and corresponds to a “support lead”. The outer end of each securing part 39 in the first direction x is exposed from the sealing resin 7 (from the side surface 75 or 76). The semiconductor elements 14 and 15 are mounted on the die pad 3 and are side by side in the first direction x.

In this embodiment, the sealing resin 7 has an inclined surface 77 that is connected to the top surface 71 and the side surface 73 and is inclined relative to the top surface 71. The pad parts 512 to which the wires 61 are bonded do not overlap with the inclined surface 77 as viewed in the thickness direction z. Thus, the semiconductor device A70 ensures that delamination of the sealing resin 7 at the pad parts 512 is detectable by SAT testing. Consequently, the semiconductor device A70 will reduce the risk of breakage of the wires 61 due to delamination of the sealing resin 7 at the pad parts 512. Also, the semiconductor device A70 has a configuration in common with the semiconductor device A10, thereby achieving the same effect as the semiconductor device A10.

As can be understood from the seventh embodiment, the present disclosure is applicable regardless of the conductive support member 2, the number, arrangement, and function of the semiconductor elements. The present disclosure is also applicable regardless of whether any portion of the conductive support member 2 is exposed from the side surface 75 or 76 of the sealing resin 7.

Further, the first and seventh embodiments are directed to a semiconductor device housed in an SOP, but the present disclosure is not limited to such. The present disclosure is applicable to semiconductor devices regardless of whether the package type is SOP.

The semiconductor device and the method for manufacturing a semiconductor device according to the present disclosure are not limited to the embodiments described above. Various modifications in design may be made freely in the specific structure of each part of the semiconductor device and each step of the manufacturing method according to the present disclosure.

The present disclosure includes embodiments described in the following clauses.

### Clause 1.

A semiconductor device comprising: a conductive support member (2) that includes a die pad (3) and a first terminal (51c), the die pad including a die pad obverse surface (31) facing a first side (z1) in a thickness direction (z), the first terminal being spaced apart from the die pad and entirely located on a first side (x1) in a first direction (x) perpendicular to the thickness direction with respect to the die pad;
a semiconductor element (11) mounted on the die pad obverse surface;
a wire (61) electrically bonded to the semiconductor element and the first terminal; and
a sealing resin (7) covering at least a portion of the conductive support member, the semiconductor element, and the wire,
wherein the sealing resin includes:
a resin top surface (71) facing the first side in the thickness direction;
a first resin side surface (73) facing the first side in the first direction, the first terminal being exposed from the first resin side surface; and
an inclined surface (77) connected to the resin top surface and the first resin side surface, the inclined surface forming a greater angle with respect to the die pad obverse surface than the resin top surface, and a bonded portion (61a) of the wire that is bonded to the first terminal does not overlap with the inclined surface as viewed in the thickness direction.

### Clause 2. (FIG. 7)

The semiconductor device according to Clause 1, wherein a first inclination angle (a) of the inclined surface with respect to the resin top surface is 25 degrees or more.

### Clause 3. (FIG. 7)

The semiconductor device according to Clause 2, wherein a second inclination angle (β) of the first resin side surface with respect to the resin top surface is greater than the first inclination angle.

### Clause 4.

The semiconductor device according to any one of Clauses 1 to 3, wherein the sealing resin further includes a second resin side surface (74) facing away from the first resin side surface in the first direction, and
the conductive support member further includes a second terminal (52c) a portion of which protrudes from the second resin side surface.

### Clause 5.

The semiconductor device according to Clause 4, further comprising a second semiconductor element (12),
wherein the conductive support member further includes a second die pad (12) spaced apart from the die pad toward a second side (x2) in the first direction, the second semiconductor element being mounted on the second die pad, and
the second terminal is entirely located on the second side in the first direction with respect to the second die pad.

### Clause 6.

The semiconductor device according to Clause 5, further comprising a second wire (62) electrically bonded to the second semiconductor element and the second terminal,
wherein a second bonded portion of the second wire that is bonded to the second terminal does not overlap with the second resin side surface as viewed in the thickness direction.

### Clause 7.

The semiconductor device according to Clause 5 or 6, wherein the semiconductor element is a control element, and
the second semiconductor element is a drive element that requires a higher voltage than the control element.

### Clause 8.

The semiconductor device according to any one of Clauses 5 to 7, further comprising an insulating element (13) that relays a signal between the semiconductor element and the second semiconductor element and insulates the semiconductor element and the second semiconductor element from each other.

### Clause 9.

The semiconductor device according to Clause 8, wherein the insulating element is mounted on the die pad.

### Clause 10. (FIGS. 9 and 10)

The semiconductor device according to any one of Clauses 4 to 9, wherein the sealing resin further includes a resin bottom surface (72) facing a second side in the thickness direction,
the first resin side surface includes a first upper region (731) connected to the inclined surface, a first lower region (732) connected to the resin bottom surface, and a first intermediate region (733) connected to the first upper region and the first lower region, the first terminal protruding from the first intermediate region,
the second resin side surface includes a second upper region (741) connected to the resin top surface, a second lower region (742) connected to the resin bottom surface, and a second intermediate region (743) connected to the second upper region and the second lower region, the second terminal protruding from the second intermediate region, and
the resin top surface, the inclined surface, the resin bottom surface, the first upper region, the first lower region, the second upper region, and the second lower region each have a first surface roughness, and the first intermediate region and the second intermediate region each have a second surface roughness, where the first surface roughness is greater than the second surface roughness.

### Clause 11.

The semiconductor device according to any one of Clauses 1 to 10, wherein the sealing resin further includes a third resin side surface (75) and a fourth resin side surface (76) facing away from each other in a second direction perpendicular to the thickness direction and the first direction, and
the conductive support member is not exposed from the third resin side surface and the fourth resin side surface.

### Clause 12. (Sixth Embodiment, FIGS. 21 and 22)

The semiconductor device according to Clause 11, wherein the sealing resin includes a first displaced part (75a) that is displaced from the third resin side surface in the second direction and that extends in the thickness direction.

### Clause 13. (Fifth Embodiment, FIG. 20)

The semiconductor device according to any one of Clauses 1 to 12, wherein the sealing resin has a first dimension (T1) on the first side determined with reference to the die pad in the thickness direction and a second dimension (T2) on the second side determined with reference to the die pad in the thickness direction, where the first dimension is greater than the second dimension.

### Clause 14. (FIGS. 12 to 16)

A method for manufacturing a semiconductor device, the method comprising:
bonding a semiconductor element (11) to a lead frame obverse surface (81A) of a lead frame (81) facing a first side in a thickness direction of the lead frame;
bonding a wire (61) to the semiconductor element and the lead frame;
forming a sealing resin (7) covering at least a portion of the lead frame, the semiconductor element, and the wire;
bending an exposed portion of the lead frame that is exposed from the sealing resin; and
cutting the exposed portion,
wherein in the forming of a sealing resin, the sealing resin (7) is formed with a resin top surface (71) facing the first side in the thickness direction, a first resin side surface (73) from which a portion of the lead frame is exposed, and an inclined surface (77) connected to the resin top surface and the first resin side surface and forming a greater angle with respect to the lead frame obverse surface than the resin top surface, where the inclined surface does not overlap with a bonded portion (61a) of the wire that is bonded to the lead frame as viewed in the thickness direction.

### Clause 15. (FIGS. 15 and 16)

The method according to Clause 14,
wherein the lead frame is not cut before the bending, and
the cutting is performed after the bending.

### REFERENCE NUMERALS

A10, A20, A30, A40, A50, A60, A70: semiconductor device
11, 12, 14, 15: semiconductor element 13: insulating element
2: conductive support member 3: die pad
31: obverse surface 32: reverse surface
39: securing part 4: die pad
41: obverse surface 42: reverse surface
51, 51a, 51b, 51c: input terminal 511: lead part
512: pad part 52, 52a, 52b, 52c: output terminal
521: lead part 522: pad part
61, 62, 63, 64: wire 61a: bonded portion
7: sealing resin 71: top surface
72: bottom surface 73: side surface
731: upper region 732: lower region
733: intermediate region 74: side surface
741: upper region 742: lower region
743: intermediate region 75: side surface
751: upper region 752: lower region
753: intermediate region 75a: slot
76: side surface 761: upper region
762: lower region 763: intermediate region
76a: slot 77, 78: inclined surface
81: lead frame 81A: obverse surface
81B: reverse surface 811: outer frame
812A: die pad 812B: die pad
813: first lead 814: second lead
816: dam bar

1. A semiconductor device comprising:
a conductive support member that includes a die pad and a first terminal, the die pad including a die pad obverse surface facing a first side in a thickness direction, the first terminal being spaced apart from the die pad and entirely located on a first side in a first direction perpendicular to the thickness direction with respect to the die pad;
a semiconductor element mounted on the die pad obverse surface;
a wire electrically bonded to the semiconductor element and the first terminal; and
a sealing resin covering at least a portion of the conductive support member, the semiconductor element, and the wire,
wherein the sealing resin includes:
a resin top surface facing the first side in the thickness direction;
a first resin side surface facing the first side in the first direction, the first terminal being exposed from the first resin side surface; and
an inclined surface connected to the resin top surface and the first resin side surface, the inclined surface forming a greater angle with respect to the die pad obverse surface than the resin top surface does, and
a bonded portion of the wire that is bonded to the first terminal does not overlap with the inclined surface as viewed in the thickness direction.

2. The semiconductor device according to claim 1, wherein a first inclination angle of the inclined surface with respect to the resin top surface is 25 degrees or more.

3. The semiconductor device according to claim 2, wherein a second inclination angle of the first resin side surface with respect to the resin top surface is greater than the first inclination angle.

4. The semiconductor device according to claim 1, wherein the sealing resin further includes a second resin side surface facing away from the first resin side surface in the first direction, and
the conductive support member further includes a second terminal a portion of which protrudes from the second resin side surface.

5. The semiconductor device according to claim 4, further comprising a second semiconductor element,
wherein the conductive support member further includes a second die pad spaced apart from the die pad toward a second side in the first direction, the second semiconductor element being mounted on the second die pad, and
the second terminal is entirely located on the second side in the first direction with respect to the second die pad.

6. The semiconductor device according to claim 5, further comprising a second wire electrically bonded to the second semiconductor element and the second terminal,
wherein a second bonded portion of the second wire that is bonded to the second terminal does not overlap with the second resin side surface as viewed in the thickness direction.

7. The semiconductor device according to claim 5, wherein the semiconductor element is a control element, and
the second semiconductor element is a drive element that requires a higher voltage than the control element.

8. The semiconductor device according to claim 5, further comprising an insulating element that relays a signal between the semiconductor element and the second semiconductor element and insulates the semiconductor element and the second semiconductor element from each other.

9. The semiconductor device according to claim 8, wherein the insulating element is mounted on the die pad.

10. The semiconductor device according to claim 4, wherein the sealing resin further includes a resin bottom surface facing a second side in the thickness direction,
the first resin side surface includes a first upper region connected to the inclined surface, a first lower region connected to the resin bottom surface, and a first intermediate region connected to the first upper region and the first lower region, the first terminal protruding from the first intermediate region,
the second resin side surface includes a second upper region connected to the resin top surface, a second lower region connected to the resin bottom surface, and a second intermediate region connected to the second upper region and the second lower region, the second terminal protruding from the second intermediate region, and
the resin top surface, the inclined surface, the resin bottom surface, the first upper region, the first lower region, the second upper region, and the second lower region each have a first surface roughness, and the first intermediate region and the second intermediate region each have a second surface roughness, where the first surface roughness is greater than the second surface roughness.

11. The semiconductor device according to claim 1, wherein the sealing resin further includes a third resin side surface and a fourth resin side surface facing away from each other in a second direction perpendicular to the thickness direction and the first direction, and
the conductive support member is not exposed from the third resin side surface and the fourth resin side surface.

12. The semiconductor device according to claim 11, wherein the sealing resin includes a first displaced part that is displaced from the third resin side surface in the second direction and that extends in the thickness direction.

13. The semiconductor device according to claim 1, wherein the sealing resin has a first dimension on the first side determined with reference to the die pad in the thickness direction and a second dimension on the second side determined with reference to the die pad in the thickness direction, where the first dimension is greater than the second dimension.

14. A method for manufacturing a semiconductor device, the method comprising:
bonding a semiconductor element to a lead frame obverse surface of a lead frame facing a first side in a thickness direction of the lead frame;
bonding a wire to the semiconductor element and the lead frame;
forming a sealing resin covering at least a portion of the lead frame, the semiconductor element, and the wire;
bending an exposed portion of the lead frame that is exposed from the sealing resin; and
cutting the exposed portion,
wherein in the forming of a sealing resin, the sealing resin is formed with a resin top surface facing the first side in the thickness direction, a first resin side surface from which a portion of the lead frame is exposed, and an inclined surface connected to the resin top surface and the first resin side surface and forming a greater angle with respect to the lead frame obverse surface than the resin top surface does, where the inclined surface does not overlap with a bonded portion of the wire that is bonded to the lead frame as viewed in the thickness direction.

15. The method according to claim 14, wherein the lead frame is not cut before the bending, and
the cutting is performed after the bending.
